(19) United States
(12) Patent Application Publication
(10) Pub. No.: US 2014/0001495 A1
(43) Pub. Date: Jan. 2, 2014

(54) LIGHT EMITTING DIODE LAMP

(71) Applicant: ADVANCED OPTOELECTRONIC TECHNOLOGY, INC., Hsinchu Hsien (TW)

(72) Inventors: CHIEN-CHUNG PENG, Hukou (TW); TZU-CHIEN HUNG, Hukou (TW); CHIA-HUI SHEN, Hukou (TW)

(73) Assignee: ADVANCED OPTOELECTRONIC TECHNOLOGY, INC., Hsinchu Hsien (TW)

(21) Appl. No.: 13/890,257

(22) Filed: May 9, 2013

(30) Foreign Application Priority Data
Jun. 29, 2012 (CN) 2012102209991

(51) Int. Cl. H01L 33/50

(52) U.S. Cl. CPC H01L 33/502
USPC 257/88; 257/98

(57) ABSTRACT

An exemplary LED lamp includes a main body, a phosphor layer and an LED module. The main body is an elongated tube. The phosphor layer is formed on an inner surface of the main body. The LED module includes a circuit board mounted on an outer surface of the main body and an LED chip mounted on the circuit board. Light emitted from the LED chip radiates into an interior of the main body to excite the phosphor layer.

### BACKGROUND

1. Technical Field

The disclosure generally relates to semiconductors, and more particular to a light emitting diode (LED) lamp having stable and reliable performance.

2. Description of Related Art

A conventionally LED lamp includes a circuit board and an LED package mounted on the circuit board and electrically connecting a circuit of the circuit board. The LED package includes an LED chip and a plurality of phosphor powder directly enclosed the LED chip therein. When the LED chip is lighted, heat generated from the LED chip heats the phosphor powder. The phosphor powder is prone be aged for bearing a long time heating.

What is needed is an LED lamp which can overcome the problem of the prior art.

### BRIEF DESCRIPTION OF THE DRAWINGS

FIG. 1 is a front view of an LED lamp according to an exemplary embodiment of the present disclosure.

FIG. 2 is a cross sectional view of the LED lamp of FIG. 1, taken along II-II line thereof, wherein two LED modules are disassembled from a main body of the LED lamp.

FIG. 3 is similar to FIG. 2 except that the LED modules are assembled to the main body.

### DETAILED DESCRIPTION

An embodiment of an LED lamp in accordance with the present disclosure will now be described in detail below and with reference to the drawings.

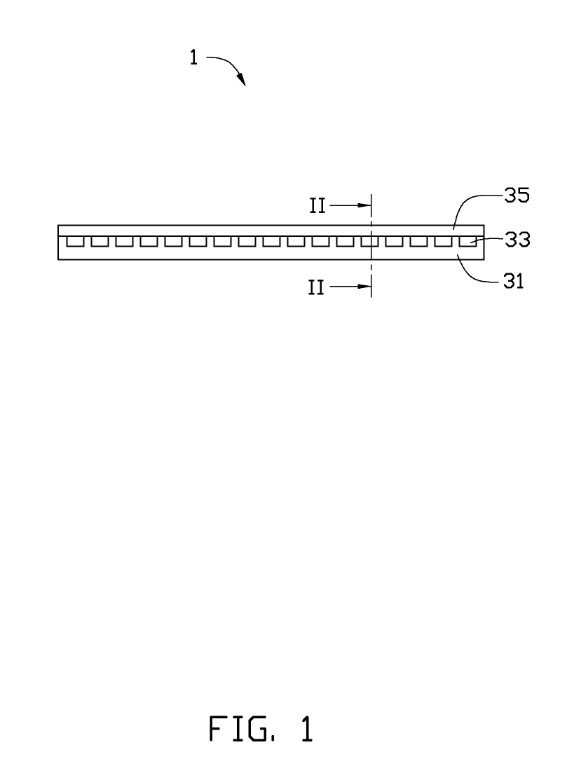

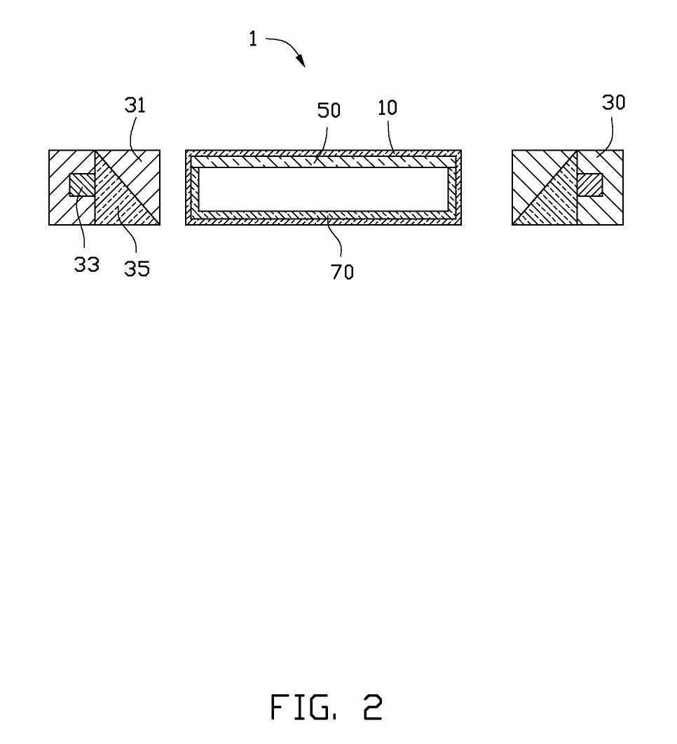

Referring to FIGS. 1-2, an LED lamp 1 in accordance with an exemplary embodiment of the disclosure includes a main body 10 and two LED modules 30 respectively mounted on two opposite sides of the main body 10.

The main body 10 is an elongated, transparent tube. The main body 10 has a rectangular cross section. A phosphor layer 70 and a reflecting layer 50 are formed on an inner surface of the main body 10 along a longitudinal direction of the main body 10. The reflecting layer 50 is formed on a top plate of the main body 10. The phosphor layer 70 is formed on a bottom plate and lateral plates of the main body 10. Top ends of the phosphor layer 70 respectively connect lateral sides of the reflecting layer 50. Thus, the reflecting layer 50 and the phosphor layer 70 cover whole of the inner surface of the main body 10. A surface area of the phosphor layer 70 is thrice that of the reflecting layer 50. In this embodiment, the reflecting layer 50 is made of barium sulfate.

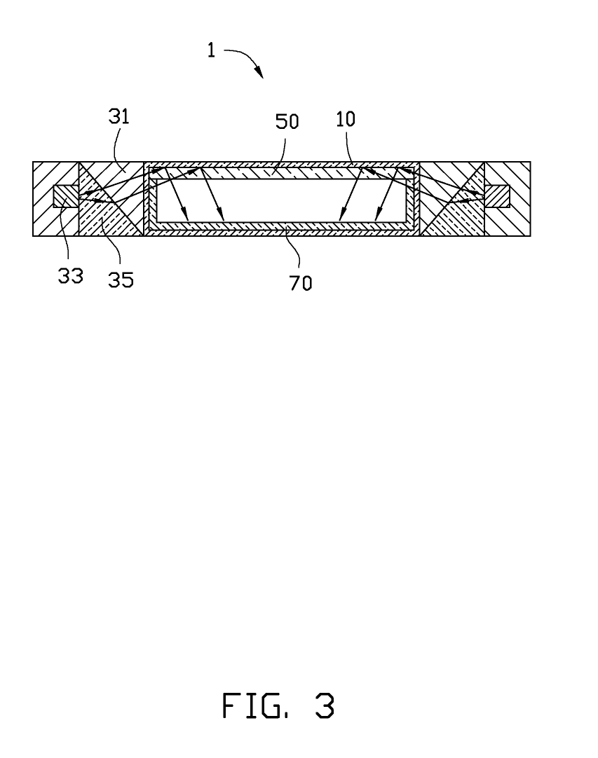

Referring to FIG. 3, each LED module 30 includes a circuit board 31, a plurality of LED chips 33 and a light guiding member 35 mounted on a side of the circuit board 31. The LED chips 33 are spaced from each other and aligned with each other along a longitudinal direction of the circuit board 31. The light guiding member 35 is located at lateral sides of the LED chips 33 to guide light emitted from the LED chips 33 to the main body 10. In this embodiment, the light guiding member 35 is a triangular pyramid, and a thickness thereof decreases from a bottom end mounted on the circuit board 31 to a top end away from the circuit board 31. The circuit boards 31 are mounted on outer surfaces of the lateral plates of the main body 10.

When the LED lamp 1 is used, light emitted from the LED chips 33 is guided by the light guiding member 35 to radiate into an interior of the main body 10. A part of light directly excites the phosphor layer 70 to obtain white light. The other part of light directly radiates towards the reflecting layer 50 and is reflected back to the phosphor layer 70 by the reflecting layer 50 to excite the phosphor layer 70 to obtain white light.

In this disclosure, the phosphor layer 70 is formed in the interior of the main body 10 and spaced from the LED chips 33, so a majority of heat generated from the LED chips 33 is directly dissipated, and a little of heat transfers to the phosphor layer 70 from the main body 10. Therefore, a life-span of the phosphor layer 70 is increased relative to the conventional LED lamp. Thus, the LED lamp 1 has stable and reliable performance.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An LED lamp comprising:
a main body, wherein the main body is an elongated tube;
a phosphor layer formed on an inner surface of the main body; and
an LED module comprising a circuit board mounted on an outer surface of the main body and an LED chip mounted on the circuit board, and light emitted from the LED chip radiating into an interior of the main body to excite the phosphor layer.

2. The LED lamp of claim 1, wherein a light guiding member is mounted on the circuit board and located at a lateral side of the LED chip to guide the light emitted from the LED chip into the main body.

3. The LED lamp of claim 2, wherein the light guiding member is a triangular pyramid, and a thickness thereof decreases from a bottom end mounted on the circuit board to a top end away from the circuit board.

4. The LED lamp of claim 1, wherein a reflecting layer is formed on the inner surface of the main body to reflect light to the phosphor layer.

5. The LED lamp of claim 4, wherein a surface area of the phosphor layer is thrice that of the reflecting layer.

6. The LED lamp of claim 4, wherein the reflecting layer is made of barium sulfate.

7. The LED lamp of claim 4, wherein the phosphor layer and the reflecting layer are arranged along a longitudinal direction of the main body.

8. The LED lamp of claim 7, wherein the reflecting layer is formed on a top of the main body, and lateral sides of the reflecting layer respectively connect opposite sides of the phosphor layer.

9. The LED lamp of claim 8, wherein the main body has a rectangular cross section, the reflecting layer is formed on a top plate of the main body, and the phosphor layer is formed on a bottom plate and lateral plates of the main body.

10. The LED lamp of claim 9, wherein the circuit board is mounted on an outer surface of the lateral plate.

11. An LED lamp comprising:
a main body, wherein the main body is an elongated tube;
a phosphor layer formed on an inner surface of the main body; and
two LED modules, each LED module comprising a circuit board and an LED chip mounted on the circuit board, the circuit boards of the LED modules respectively mounted on opposite sides of an outer surface of the main body, and light emitted from the LED chips radiating into an interior of the main body to excite the phosphor layer.

12. The LED lamp of claim 11, wherein each LED module comprises a plurality of LED chips spaced from each other and aligned with each other along a longitudinal direction of the circuit board.

13. The LED lamp of claim 12, wherein a reflecting layer is formed on the inner surface of the main body to reflect light to the phosphor layer.

14. The LED lamp of claim 13, wherein the phosphor layer and the reflecting layer are arranged along a longitudinal direction of the main body.

15. The LED lamp of claim 14, wherein lateral sides of the phosphor layer respectively connect opposite sides of the reflecting layer, and the circuit boards correspond to joints of the phosphor layer and the reflecting layer.

16. The LED lamp of claim 11, wherein a light guiding member is mounted on the circuit board to guide the light emitted from the LED chip into the main body.

17. The LED lamp of claim 16, wherein the light guiding member is a triangular pyramid, and a thickness thereof decreases from a bottom end mounted on the circuit board to a top end away from the circuit board.
